(19) United States
(12) Patent Application Publication
(10) Pub. No.: US 2016/0276610 A1
(43) Pub. Date: Sep. 22, 2016

(54) POLYMER SOLAR CELL USING A LOW-TEMPERATURE, SOLUTION-PROCESSED METAL-OXIDE THIN FILM AS A HOLE-EXTRACTION LAYER

(71) Applicants: Xiong GONG, Hudson, OH (US); Bohao LI, Hoover, AL (US); He REN, Akron, OH (US)

(72) Inventors: Xiong Gong, Hudson, OH (US); Bohao LI, Hoover, AL (US); He Ren, Akron, OH (US)

(73) Assignee: The University of Akron, Akron, OH (US)

(21) Appl. No.: 15/031,922

(22) PCT Filed: Nov. 7, 2014
(86) PCT No.: PCT/US14/64538

§ 371 Date: Apr. 25, 2016

Related U.S. Application Data
(60) Provisional application No. 61/901,022, filed on Nov. 7, 2013.

(51) Int. Cl. H01L 51/42; H01L 51/44; H01L 51/00

(52) U.S. Cl. CPC H01L 51/4253; H01L 51/0003; H01L 51/442; H01L 51/0047; H01L 2251/303; H01L 2251/308; H01L 2251/301

(57) ABSTRACT

A polymer solar cell includes a low temperature, solution-processed metal-oxide thin film, such as molybdenum-oxide (MoOₓ), as a hole-extraction layer (HEW. The low temperature processing allows the metal-oxide thin film to achieve a smoother surface, which allows the thin film to have enhanced light transparency and increased electrical conductivity over that of conventional PEDOT:PSS thin films. As such, the polymer solar cell, which utilizes the metal-oxide thin film as a hole-extraction layer, is able to achieve enhanced power conversion efficiency over conventional polymer solar cells that use PEDOT:PSS as a hole-extraction layer.

### CROSS-REFERENCE TO RELATED APPLICATION

This application claims the benefit of U.S. Provisional Application No. 61/901,022 filed on Nov. 7, 2013, the content of which is incorporated herein by reference.

### TECHNICAL FIELD

The present invention generally relates to solar cells. In particular, the present invention relates to polymer solar cells. More particularly, the present invention relates to polymer solar cells that utilize a low-temperature solution-processed metal-oxide thin film, as a hole-extraction layer (HEL).

### BACKGROUND OF THE INVENTION

In the past two decades, bulk heterojunction (BHJ) polymer solar cells (PSC) have gained increased attention due to their advantages over traditional inorganic solar cells. Such advantages of polymer solar cells include: the ability of the solar cell to be physically flexible, low cost of manufacturing, lightweight design, large surface area, clean and quiet operation, and fabrication simplicity. During the fabrication of such polymer solar cells, the bulk heterojunction (BHJ) composite layer is sandwiched on one side by a layer of poly(3,4-ethylenedioxythiophene): poly(styrenesulfonate), or PEDOT:PSS, which is coated with an indium-tin-oxide (ITO) anode, while the other side of the BHJ composite material is sandwiched by a low work-function cathode, such as calcium (Ca)/aluminum (Al) for example. However, the acidic PEDOT:PSS often etches the ITO anode, and causes the degradation of the polymer solar cell. One solution that has been used to overcome this problem has been to substitute the PEDOT:PSS layer with a stable metal-oxide layer, which provides suitable energy level alignment between the ITO anode and the BHJ active layer.

While many metal-oxides have been utilized as a hole-extraction layer (HEL) in polymer solar cells, the operating efficiencies achieved by their use have not been satisfactory. For example, molybdenum-oxide (MoOₓ) is one such metal-oxide, which is suitable for use in solar cells in view of its light transparency in the visible range, good stability and hole mobility. However, the operating efficiencies of polymer solar cells (PSC) that incorporate vacuum-deposited metal-oxides as hole-extraction layers were comparable to polymer solar cells using PEDOT:PSS as an anode buffer layer (hole-extraction layer), whereas the operating efficiencies of polymer solar cells (PSC) incorporating solution-processed metal-oxides were lower than those using PEDOT:PSS as an anode buffer layer (hole-extraction layer). This lower operating efficiency that is associated with solution-processed MoOₓ-based polymer solar cells is generally due to the fact that in order to achieve sufficient hole-transport during solar cell operation, the MoOₓ thin film must be thermally annealed at an elevated temperature. Unfortunately, the plastic substrate that is used for fabricating polymer solar cells (PSC) are unable to sustain elevated annealing temperatures, and as a result form polymer solar cells that have reduced optical transparency, as well as reduced thermal and dimensional stability at high temperature. In addition, high temperature annealing of large-area metal-oxides, which is required in the fabrication of polymer solar cells that use solution-processed metal oxides as a hole-extraction layer is generally incompatible with the low-cost manufacturing techniques typically used in fabricating polymer solar cells.

Therefore, there is a need for a polymer solar cell that utilizes a metal-oxide hole-extraction layer (HEL) that is solution-processed at low temperature, such as room temperature, which does not require thermal annealing so that it is compatible with the plastic substrate used to form a polymer solar cell (PSC). In addition, there is a need for a method for fabricating low-temperature solution-processed polymer solar cells (PSC), which has improved performance over typical polymer solar cells that utilize PEDOT:PSS as a hole extraction layer. There is also a need for a polymer solar cell that utilizes a low-temperature solution-processed metal-oxide as a hole-extraction layer that can be fabricated at low cost.

### SUMMARY OF THE INVENTION

In light of the foregoing, it is a first aspect of the present invention to provide a non-annealed hole-extraction layer for disposing upon an anode layer of a polymer solar cell comprising a film formed from a reaction of a metal-oxide powder and methanol at a temperature of below about 150° C.

It is another aspect of the present invention to provide a method of forming a polymer solar cell comprising the steps of providing an anode layer, forming a hole-extraction layer comprising a metal-oxide that has been solution-processed at a temperature below about 150° C., disposing the hole-extraction layer upon the anode layer, disposing a polymer composite bulk heterojunction layer upon the hole-extraction layer, and disposing a cathode layer upon the bulk heterojunction layer.

### BRIEF DESCRIPTION OF THE DRAWINGS

These and other features and advantages of the present invention will become better understood with regard to the following description, appended claims, and accompanying drawings wherein:

FIG. 1 is a schematic diagram of a polymer solar cell with a hole-extraction layer (HEL) formed of a metal-oxide that is solution-processed at low temperature in accordance with the concepts of the present invention;

FIG. 2A is a graph showing the transparency spectra of a MoOₓ thin film that has been solution-processed at room temperature, without thermal annealing in accordance with the concepts of the present invention, and MoOₓ thin films annealed at different temperatures, in comparison with a PEDOT:PSS thin film;

FIG. 2B is a graph showing the current density versus voltage of polymer solar cells using different hole-extraction layers (anode buffer layers), including hole-extraction layers formed of a MoOₓ thin film that has been solution-processed at room temperature, without thermal annealing in accordance with the concepts of the present invention, MoOₓ thin films annealed at different temperatures, and a PEDOT:PSS thin film;

FIG. 3A is an atomic force microscope (AFM) image of bare ITO having an RMS of about 1.454 nm;

FIG. 3B is an atomic force microscope (AFM) image of MoOₓ that has been solution-processed at room temperature, and casted without any thermal annealing, having an RMS of about 1.272 nm in accordance with the concepts of the present invention;

FIG. 3C is an atomic force microscope (AFM) image of MoOₓ thermally annealed at 120° C. having an RMS of about 1.637 nm;

FIG. 3D is an atomic force microscope (AFM) image of MoOₓ thermally annealed at 250° C. having an RMS of about 1.009 nm;

FIG. 4 is a graph showing an x-ray photoelectron spectroscopy (XPS) image of the spectra of a molybdenum (Mo) 3d core level from a MoOₓ thin film that is solution-processed at room-temperature, without thermal annealing, with major peaks denoted as (a) Mo⁶⁺ (235.8 eV) and (b) Mo⁶⁺ (235.8 eV) and minor peaks denotes as (c) Mo⁵⁺ (234.0 eV) and (d) Mo⁵⁺ (235.8 eV) in accordance with the concepts of the present invention;

FIG. 5A is a schematic image showing the peak current of a MoOₓ thin film that has been solution-processed at room-temperature without any thermal annealing treatment in accordance with the concepts of the present invention; and

FIG. 5B is a schematic image showing the peak current of a MoOₓ thin film thermally annealed at 250° C.

### DETAILED DESCRIPTION OF THE INVENTION

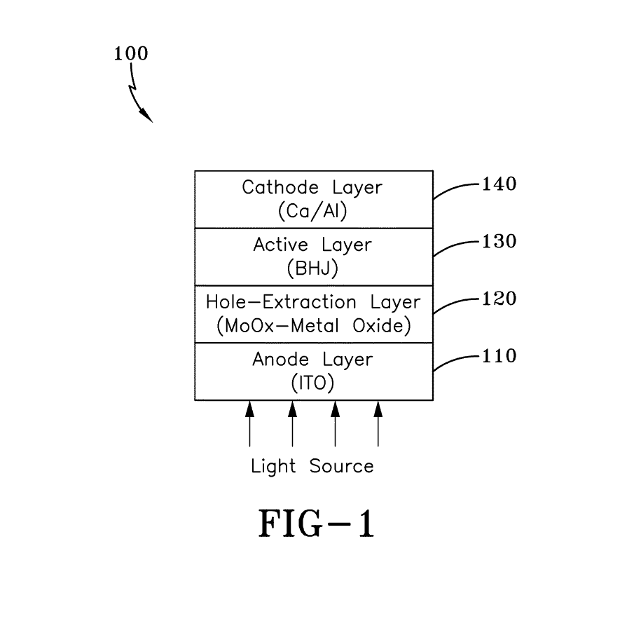

A polymer solar cell (PSC) utilizing a low-temperature, solution-processed metal-oxide is generally referred to by numeral 100, as shown in FIG. 1 of the drawings. The PSC 100 comprises a layered structure that is formed using any suitable technique. In particular, the polymer solar cell 100 includes an anode layer 110 that may be formed of any suitable material, such as indium-tin-oxide (ITO) for example. It should be appreciated that the anode 110 is at least partially transparent to light. Disposed upon the anode layer 110 is a hole-extraction layer 120 (anode buffer layer), which comprises a metal-oxide, such as molybdenum oxide (MoOₓ, where “x” may be less than or equal to 3), which has been solution-processed at low temperature. It should also be appreciated that the hole-extraction layer 120 is at least partially transparent to light. A bulk heterojunction (BHJ) active layer 130 is disposed upon the hole-extraction layer 120, and is configured to receive solar energy from a light source, such as the sun, for conversion to electrical current. The BHJ active layer 130 may comprise any suitable polymer composite material, such as a material formed from the combination/blend of polymers, such as conjugated polymers, and fullerene derivatives. For example, the blend of conjugated polymers and fullerene derivatives for use as the BHJ active layer 130 may comprise PTB7-F20:PC₇₁BM for example, the chemical structures for which are shown below.

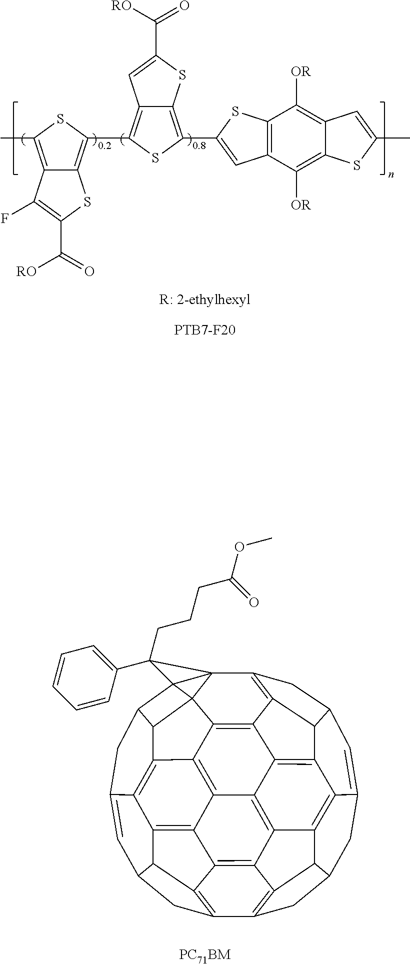

In addition, a cathode layer 140, which may be formed of any suitable material, such as calcium (Ca)/aluminum (Al) for example, is disposed upon the active layer 130.

It should be appreciated that while the following discussion relates to the use of molybdenum oxide (MoOₓ) as a low-temperature solution-processed metal oxide for use as the hole-extraction layer 120, any other suitable metal-oxide may be utilized, including but not limited to: V₂O₅, Fe₃O₄, NiO, Sb₂O₃, Cr₂O₃, p-type metal oxides, and the like. The MoOₓ hole-extraction layer 120 used in the polymer solar cell (PSC) 100 was spin-casted from a MoOₓ methanol solution. Specifically, to form the MoOₓ methanol solution, a solution was initially prepared by vigorous stirring and effective radiating, as 100 mL H₂O₂ (concentration of 30%) was slowly added into 10 grams of molybdenum (Mo) powder in a clean beaker, which was set upon an ice-water bath to aid the radiating process. The resultant solution was then placed in a centrifuge to remove any rudimental substances to obtain a clear solution. Next, the clear solution was dried by distillation to produce a dried MoOₓ powder. Finally, a “solution-processing” step was performed, whereby the dried MoOₓ powder was then dissolved in methanol at room temperature to form the “solution-processed” MoOₓ thin film, which is used as the hole-extraction layer 120. It should be appreciated that the term “room temperature” as used herein is defined as a temperature that is from about 20° C. to 23° C. However, it should be appreciated that the “solution-processing” step in which the dried MoOₓ powder is dissolved in methanol may take place at “low temperatures”, which are defined as temperatures at or below about 150° C., for the preparation of the MoOₓ film for use as the hole-extraction layer 120.

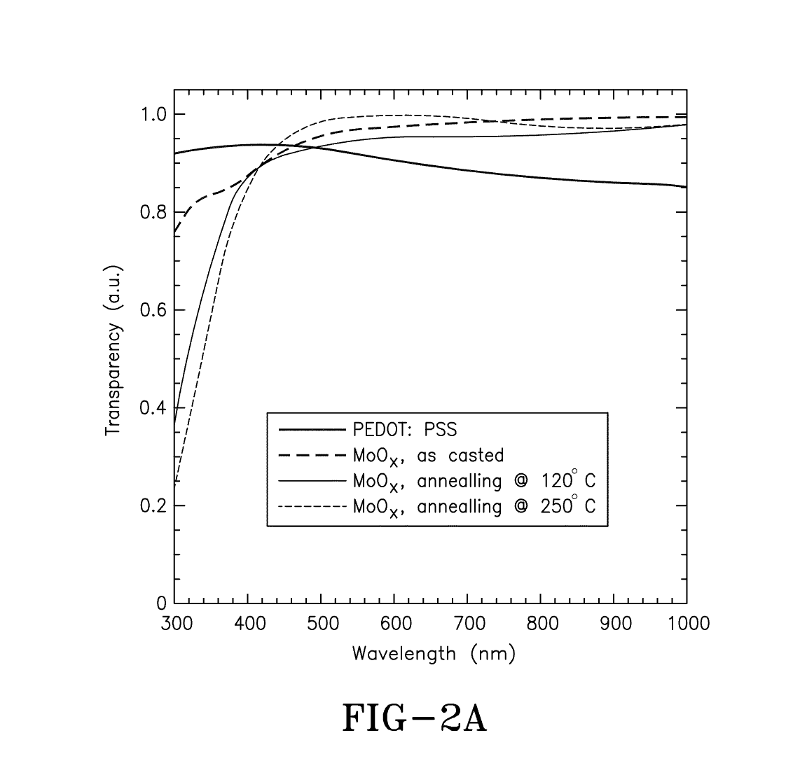

FIG. 2A shows the comparison of the light transmission spectra of the MoOₓ thin film of the present invention, which have been treated or annealed at different temperatures, including: where the MoOₓ thin film has been solution-proceed at room temperature and casted without any thermal annealing; where the MoOₓ thin film has been annealed at 120° C.; and where the MoOₓ thin film has been annealed at 250° C. For comparison, FIG. 2A also shows the light transmission spectra of a conventional PEDOT:PSS thin film. As such, the MoOₓ thin film provide a high transmittance of light in the visible range, which is desirable when used for the hole-extraction layer (HEL) 120 that is disposed between the ITO anode layer 110 and the BHJ polymer composite active layer 130 of the polymer solar cell 100, as shown in FIG. 1.

In particular, as shown in FIG. 2A, greater than 90% transparency of light at wavelengths ranging from 500 to 1000 nm is observed from MoOₓ thin films that are treated or annealed at different temperatures. The weak absorption of light at wavelengths from 800 to 900 nm is attributed to free electrons being trapped by oxygen vacancies in the MoOₓ thin films. Nevertheless, the light transmittance of the various MoOₓ thin films is higher than that of the conventional PEDOT:PSS thin film. As a result, more visible light is able to be transmitted through the ITO layer 110 and the MoOₓ layer 120 for receipt into the BHJ active layer 130 without significant light absorption losses, as compared to conventional polymer solar cells (PSC) using PEDOT:PSS. Thus, MoOₓ thin film, which has been solution-processed at low temperature, such as room temperature, without thermal annealing, has desirable properties for use as the hole-extraction layer (HEL) 120.

In addition, the effect of MoOₓ thin films on the operating performance of the polymer solar cell 100 was investigated, whereby the anode layer was formed of ITO, the hole extraction layer 120 was formed of MoOₓ, the BHJ layer 130 comprised PTB7-F20:PC₇₁BM, and the anode layer 140 comprised a combination of calcium (Ca) and aluminum (Al). In addition, the operating performance of the polymer solar cell 100 of the present invention was compared to a polymer solar cell 100 in which PEDOT:PSS was used as the hole-extraction layer 120. As such, the resultant J-V curves of the two polymer solar cells when subjected to AM 1.5G illumination cells are shown in FIG. 2B.

Thus, when subjected to a light intensity of 100 mW/cm² the polymer solar cell using a conventional PEDOT:PSS-based hole-extraction layer (HEL) achieved an open-circuit voltage (Voc) of 0.60 V, a short-circuit current density (Jsc) of 11.92 mA/cm², a fill factor (FF) of 62% and a corresponding power conversion efficiency (PCE) of 4.43%.

Under the same illumination conditions, the polymer solar cell 100 using a MoOₓ-based hole-extraction layer (HEL) that was solution-processed at low temperature (room temperature) and spin-casted without any annealing treatment obtained a Voc of about 0.65 V, a short-circuit current density (Jsc) of about 14.2 mA/cm², a fill factor (FF) of about 50.7% and a power conversion efficiency (PCE) of about 4.67%.

In addition, the polymer solar cell 100 using a MoOₓ-based hole-extraction layer (HEL), which was annealed at 120° C. achieved a Voc of about 0.67 V; a Jsc of about 13.0 mA/cm², a FF of about 52.8%, and a power conversion efficiency (PCE) of about 4.62%.

Finally, the polymer solar cell 100 using a MoOₓ-based hole-extraction layer (HEL), which was annealed at 250° C. achieved a Voc of about 0.65 V, a Jsc of about 12.4 mA/cm², a FF of about 53.2%, and a corresponding power conversion efficiency (PCE) of about 4.63%.

Thus, among these polymer solar cells (PSC), the PSC that utilized a casted MoOₓ thin film that was solution-processed at room temperature without any thermal annealing as a hole-extraction layer (HEL) 120 provided the best operating performance.

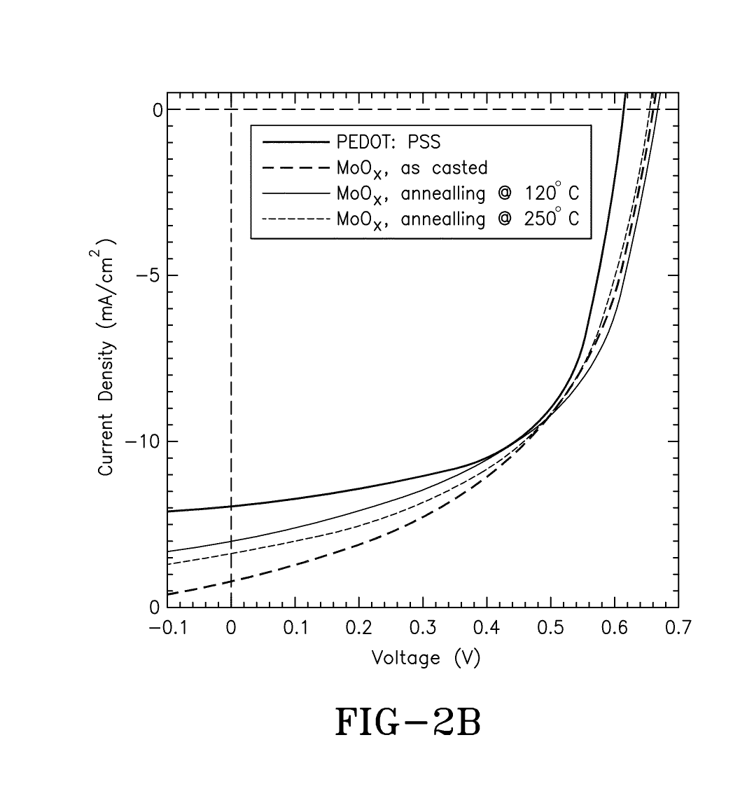

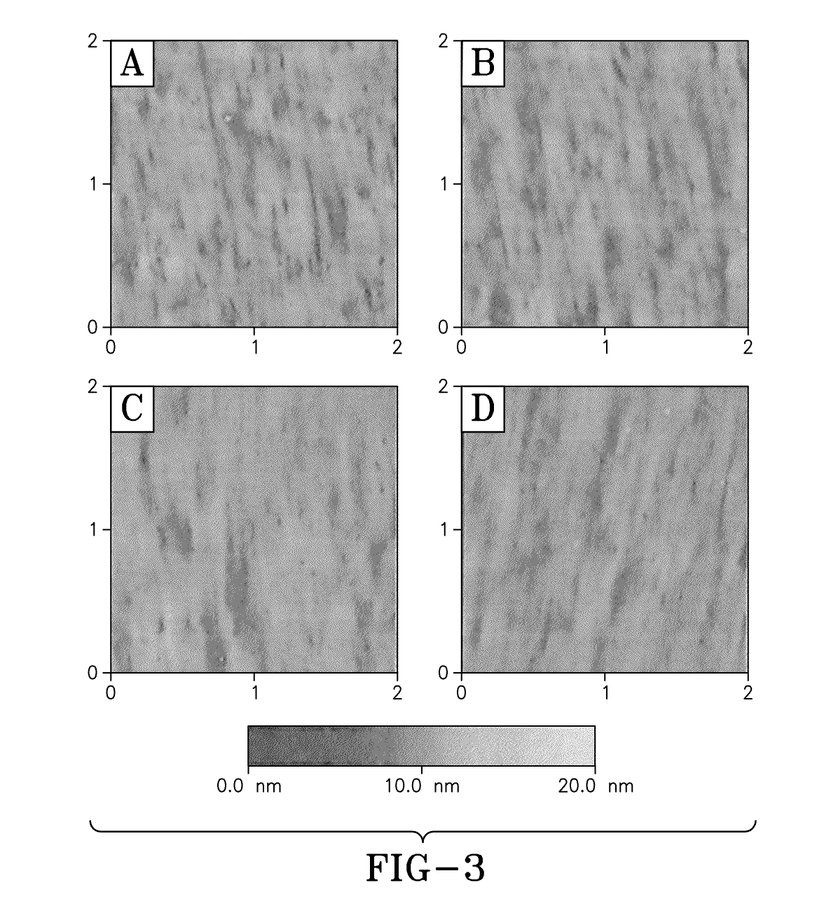

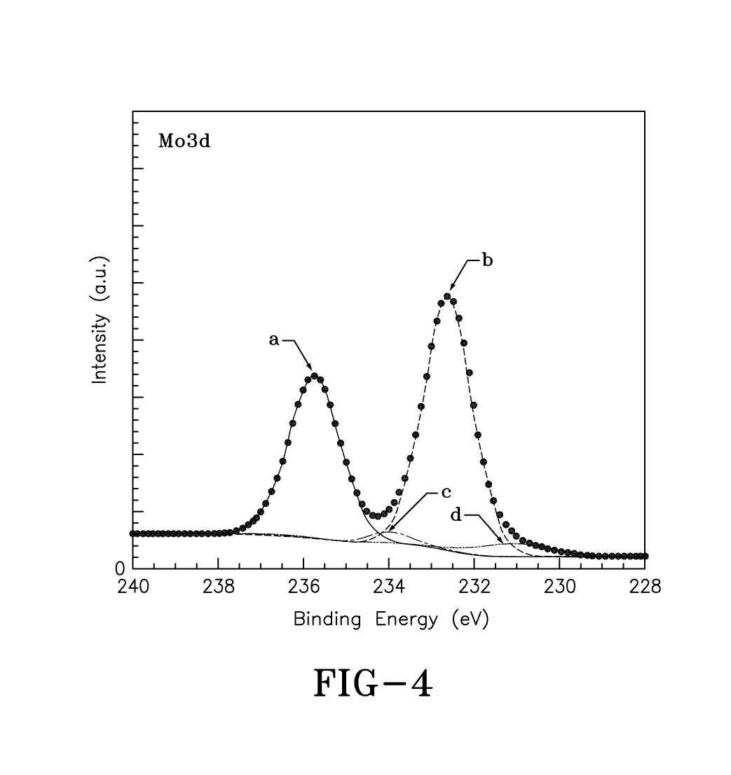

In order to understand the underlying performance of the polymer solar cell 100 using a MoOₓ-based thin film as a hole-extraction layer (HEL) 120, the surface morphology of the MoOₓ thin films was investigated using atomic force microscopy (AFM). In particular, tapping mode AFM images of a MoOₓ thin film with different annealing conditions are shown in FIG. 3, where the MoOₓ thin film was spin-casted on a pre-cleaned ITO substrate. The root-mean square (RMS) surface roughness of a MoOₓ thin film that was solution-processed at room temperature, and casted without any thermal annealing treatment, was 1.272 nm (designated as “B”). This was smaller than 1.454 nm of bare ITO (designated as “A”), and that of 1.637 nm of a MoOₓ thin film that was thermally annealed at 120° C. (designated as “C”). However, the root-mean square (RMS) surface roughness of 1.272 nm of the MoOₓ thin film that was not thermally annealed is larger than the 1.099 nm RMS surface roughness of the MoOₓ thin film that is annealed at 250° C. (designated as “D”). In any event, the smooth surface of the room temperature solution-processed MoOₓ thin film, which was not thermally annealed, allows the bulk heterojunction (BHJ) composite layer 130 to be easily deposited onto of the MoOₓ thin layer 120, and as a result, the polymer solar cell 100 formed with such material is able to achieve high operating efficiencies.

The stoichiometric composition of MoOₓ thin films was evaluated by x-ray photoelectron spectroscopy (XPS), where FIG. 4 presents XPS spectra of the MoOₓ thin film that has been solution-processed at low temperature, such as room temperature, without any thermal annealing treatment. Decomposition of the XPS spectrum reveals two 3d doublets, which correspond to two different oxidation states, in the form of a Gaussian function for the Mo 3d spectrum. It is shown that the major peak appears at the binding energy of 232.6 eV, designated “a”, and 235.8 eV, designated “b”, which correspond to the 3d doublet of Mo⁶⁺. The minor peak is centered at 234 eV, designated “c” and 231.1 eV, designated “d”, which are typical values of the 3d doublet of Mo⁵⁺. The molybdenum-to-oxygen stoichiometry data obtained from the XPS spectra of the MoOₓ thin films are summarized in Table 1 below (i.e. XPS compositional analysis of solution-processed MoOₓ thin films).

| | MoOₓ | | |
|---|---|---|---|
| MoOₓ | (Spin-Casted; Room | MoOₓ | MoOₓ |
| Composition | Temperature Solution- | (Annealed at | (Annealed at |
| Component | Processed) | 120° C.) | 250° C) |
| Molybdenum | 15.1 | 20.8 | 22.0 |
| Oxygen | 51.1 | 55.7 | 52.4 |
| Carbon | 33.8 | 23.5 | 25.6 |
| Mo/O Ratio | 1:3.38 | 1:2.67 | 1:2.38 |

In particular, Table 1 reveals that the ratio of molybdenum-to-oxygen increases with increased annealing temperatures, resulting in oxygen deficiency in MoOₓ thin films that are formed at high annealing temperatures. Thus, the samples of MoOₓ exhibit a more ideal MoOₓ lattice stoichiometry when annealed at lower temperatures, leading to a minimized Mo⁵⁺ and oxygen deficiency. The atomic concentration ratio of Mo⁵⁺ to Mo⁶⁺ obtained from room-temperature solution-processed MoOₓ films is around 1:3.38, which indicates less oxygen vacancies in MoOₓ, thereby resulting in high electrical conductivity. Because solar cell performance is reversely related to the density of Mo⁵⁺ species in MoOₓ thin films, whereby decreased Mo⁵⁺ and oxygen deficiency results in a polymer solar cell that has improved performance, the use of low temperature, such as room temperature, solution-processed MoOₓ thin films, allows polymer solar cells of the present invention to have an increased level of operating performance.

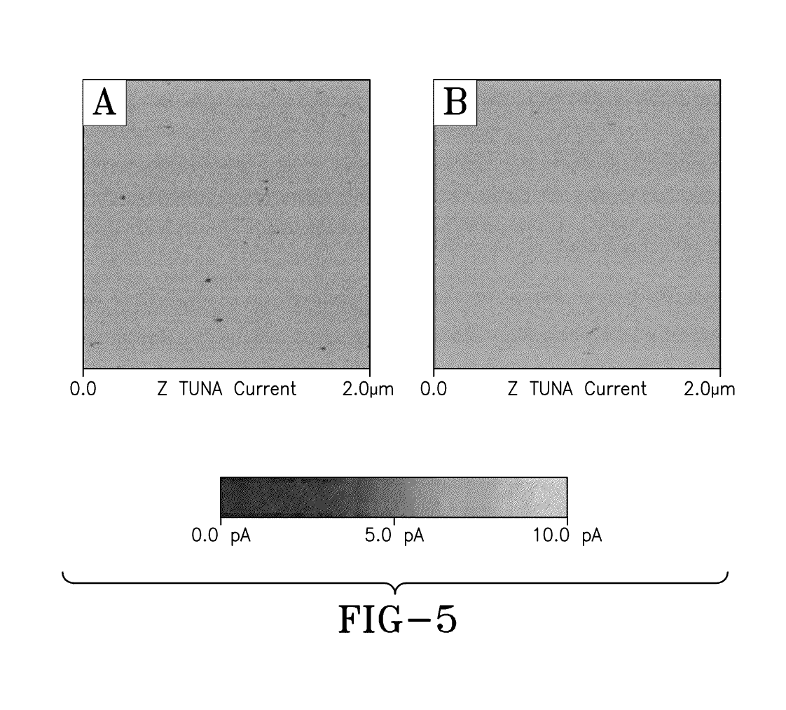

In addition, the surface electrical conductivities of MoOₓ thin films were measured using a peak force tapping tunneling AFM (PF-TUNA) module, which uses a PF-TUNA probe having a spring constant of about 0.5 N/m with a 20 nm Pt (Platinum)/Ir (Iridium) coating on both the front and rear. The spring currents were measured with a bias voltage applied to the sample of MoOₓ. A ramp rate of 0.4 Hz and the force set point of approximately 60 nN were used for both thin films. As shown in FIG. 5, the peak currents of an MoOₓ thin film without thermal annealing (FIG. 5A) is compared with that of an MoOₓ thin film that was thermally annealed at 250° C. (FIG. 5B). In particular, the surface electrical conductivity of the MoOₓ thin film with thermal annealing at 250° C. was 0.601 pA, while the surface electrical conductivity of the MoOₓ thin film without thermal annealing is 0.642 pA. Thus, the surface electrical conductivity of MoOₓ thin films without any thermal annealing is higher than that of MoOₓ thin films that are thermal annealed at 250° C. As a result, the efficiency from polymer solar cells using MoOₓ thin films without any thermal annealing as a hole-extraction layer (HEL) is higher than that using MoOₓ thin films with thermal annealing at 250° C.

Thus, metal-oxide thin films that are solution-processed at low temperature, such as room temperature, for use as a hole-extraction layer (HEL) of the present invention, without any thermal annealing, provides many advantages over that of traditional PEDOT:PSS-based solar cells. For example, such low temperature solution-processed metal oxides provide a smoother surface, better transparency and higher electrical conductivity than that of PEDOT:PSS based thin films used for a hole-extraction layer (HEL), thus leading to enhanced efficiency of the polymer solar cell 100.

Based on the foregoing, the advantages of the present invention are readily apparent. The main advantage of this invention is to provide a polymer solar cell using a low-temperature, solution-processed metal-oxide thin film hole-extraction layer that has operating efficiencies similar to those of polymer solar cells using PEDOT:PSS as anode buffer layer, where the sol-gel-derived MoOₓ thin film has to be thermally annealed at 250° C. to ensure that it has sufficient hole-transporting properties. Still another advantage of the present invention is that a polymer solar cell using low temperature solution-processed metal-oxide as a hole extraction layer provides enhanced transparency and enhanced electrical conductivity over that of typical PEDOT:PSS hole extraction layers. Another advantage of the present invention is that a low temperature solution-processed metal-oxide may be used in a polymer solar cell as a hole-extraction layer without using a thermal annealing process, which may lead to damage of the polymer solar cell. Still another advantage of the present invention is that a water-free, room-temperature solution-processed metal-oxide thin film for use as a hole-extraction layer for a polymer solar cell is compatible with a broad selection of solar cell substrates, such as plastic substrates, which are not compatible with conventional hole-extraction layer fabrication techniques, which require high-temperature thermal annealing.

Thus, it can be seen that the objects of the present invention have been satisfied by the structure and its method for use presented above. While in accordance with the Patent Statutes, only the best mode and preferred embodiment has been presented and described in detail, it is to be understood that the present invention is not limited thereto or thereby. Accordingly, for an appreciation of the true scope and breadth of the invention, reference should be made to the following claims.

What is claimed is:

1. A non-annealed hole-extraction layer for disposing upon an anode layer of a polymer solar cell comprising:
a film formed from a reaction of a metal-oxide powder and methanol at a temperature of below about 150° C.

2. The polymer solar cell of claim 1, wherein said metal-oxide powder is formed from a metal-oxide selected from the group consisting of: MoOₓ, wherein x is less than or equal to 3, V₂O₅, Fe₃O₄, NiO, Sb₂O₃, and Cr₂O₃.

3. The polymer solar cell of claim 1, wherein said metal-oxide powder is formed from a p-type metal oxide.

4. A method of forming a polymer solar cell comprising the steps of:
providing an anode layer;
forming a hole-extraction layer comprising a metal-oxide that has been solution-processed at a temperature below about 150° C.;
disposing said hole-extraction layer upon said anode layer;
disposing a polymer composite bulk heterojunction layer upon said hole-extraction layer; and
disposing a cathode layer upon said bulk heterojunction layer.

5. The method of claim 4, wherein said anode layer comprises indium-tin-oxide (ITO).

6. The method of claim 4, wherein said metal-oxide is selected from the group consisting of: MoOₓ, wherein x is less than or equal to 3, V₂O₅, Fe₃O₄, NiO, Sb₂O₃, and Cr₂O₃.

7. The method of claim 4, wherein said polymer composite bulk heterojunction layer comprises a combination of one or more conjugated polymers and one or more fullerene derivatives.

8. The method of claim 4, wherein said polymer composite bulk heterojunction comprises PTB7-F20:PC₇₁BM.

9. The method of claim 4, wherein said cathode layer comprises a combination of calcium and aluminum.

10. The method of claim 4, wherein the step of forming said hole-extraction layer comprises:
providing a metal-oxide solution;
drying said metal-oxide solution to form a metal-oxide powder;
dissolving said metal-oxide powder into methanol at a temperature below about 150° C. to form a dissolved metal-oxide solution; and
forming a film of said dissolved metal-oxide solution upon said anode layer of the polymer solar cell to form said hole-extraction layer.

11. The method of claim 10, wherein said metal-oxide solution comprises a mixture of a metal-oxide and H₂O_{2.}

12. The method of claim 11, wherein said metal-oxide is selected from the group consisting of: MoOₓ, wherein x is less than or equal to 3, V₂O₅, Fe₃O₄, NiO, Sb₂O₃, and Cr₂O₃.

13. The method of claim 10, wherein said drying step is performed by distilling said metal-oxide solution.

14. The method of claim 4, wherein said step of disposing said hole-extraction layer on said anode is performed by spin-casting.

15. The method of claim 4, wherein said step of forming said hole-extraction layer is performed without thermal annealing.
